(19) United States
(12) Patent Application Publication
(10) Pub. No.: US 2025/0323662 A1
(43) Pub. Date: Oct. 16, 2025

(54) ENCODING APPARATUS AND METHOD FOR PROVIDING MAXIMUM TRANSITION AVOIDANCE AND DIRECT CURRENT (DC)-BALANCED AND RUN-LENGTH LIMITED CODES

(71) Applicant: Samsung Electronics Co., Ltd., Suwonsi (KR)

(72) Inventors: Goeun Kim, Suwon-si (KR); Younghwan Chang, Suwon-si (KR); Suhwan Kim, Seoul (KR)

(73) Assignees: Samsung Electronics Co., Ltd., Suwon-si (KR); Seoul National University R&DB Foundation, Seoul (KR)

(21) Appl. No.: 19/018,880

(22) Filed: Jan. 13, 2025

(30) Foreign Application Priority Data
Apr. 15, 2024 (KR) 10-2024-0050302

(51) Int. Cl. H03M 5/14; H03M 7/46

(52) U.S. Cl. CPC H03M 5/145; H03M 7/46

(57) ABSTRACT

An encoding apparatus and a method for providing maximum transition avoidance (MTA), direct current (DC) balance, and run-length limited codes are provided. An apparatus including a transmitter connected to a signal line, wherein the transmitter includes an encoder configured to encode data bits to be transmitted through the signal line, according to pulse amplitude modulation (PAM), to convert the data bits into data symbols having multiple voltage levels. The encoder includes a logic circuit configured to provide look-up tables indicating a correlation between the data bits and the data symbols and a control circuit configured to selectively control logic operations of the logic circuit that generates the look-up tables. The look-up tables include mappings related to operation requirements of the encoder, and the operation requirements of the encoder includes a DC balance requirement and a run-length limit requirement of data symbols.

### CROSS-REFERENCE TO RELATED APPLICATION(S)

This application is based on and claims priority under 35 USC § 119 to Korean Patent Application No. 10-2024-0050302, filed on Apr. 15, 2024, in the Korean Intellectual Property Office, the disclosure of which is incorporated by reference herein in its entirety.

### BACKGROUND

The inventive concept relates to apparatuses and methods, and more particularly, to encoding apparatuses and methods for providing maximum transition avoidance (MTA) and direct current (DC)-balanced and run-length limited codes in relation to a clock and data recovery (CDR) circuit.

Efforts to make computing systems more powerful and more power efficient have led to advances in interface communications to improve throughput without increasing, ideally, reducing, power consumption. In systems, communications between chips require faster speed and wide bandwidth, so each chip includes a high-speed input/output (I/O) interface circuit, such as a serial link.

In serial link communication, a clock signal for the side receiving data through a channel is not transmitted separately, and only the data is transmitted through the channel. Accordingly, in order to process serial data, a receiver requires a CDR circuit that extracts clock information and data information from serial data. The CDR circuit of the receiver may perform an operation of generating a clock signal from data transition and synchronizing the received data with the clock signal. However, when the same data is continuously received in the CDR circuit without data transition, bit synchronization for data recovery may become difficult. Taking this into account, data having relatively low run-lengths (RL), relatively high transition density and/or DC balance may be designed to be transmitted. Run-length is a measure of a series of consecutive 0s or 1s in the data, and DC balance is a measure of the imbalance between 0s and 1s.

Some systems implement pulse-amplitude modulation 4-level (PAM4) signaling. PAM4 may be used to convert two bitstreams into a single multilevel signal (or symbol) having 4 levels (e.g., [0], [1], [2], [3] in FIG. 3). PAM4 signaling may use maximum transition avoidance (MTA) coding for eliminating maximum voltage transition (e.g., [0]→[3], [3]→[0]) between multilevel signals in a signal line. PAM4 signaling may identify the quality of signals in high-speed transmission using a data eye diagram in which the swings of signals transmitted at multiple levels are shown to overlap each other. Considering this, eye opening may be designed to be maximized.

Maintaining DC balance and limiting run-length in PAM4 signaling to which MTA coding is applied may be beneficial for high-speed communication devices.

### SUMMARY

The inventive concept provides encoding apparatuses and methods for providing maximum transition avoidance and direct current (DC)-balanced and run-length limited codes.

According to an aspect of the inventive concept, an apparatus includes a transmitter connected to a signal line, wherein the transmitter includes an encoder configured to encode data bits to be transmitted through the signal line, according to pulse amplitude modulation (PAM), to convert the data bits into data symbols having multiple voltage levels, wherein the encoder includes a logic circuit configured to provide look-up tables indicating a correlation between the data bits and the data symbols, the look-up tables including mappings related to operation requirements of the encoder, the operation requirements of the encoder including a DC balance requirement and a run-length limit requirement of the data symbols and a control circuit configured to selectively control logic operations of the logic circuit that generates the look-up tables.

According to another aspect of the inventive concept, an apparatus includes a transmitter connected to a signal line, wherein the transmitter includes an encoder configured to encode user data to be transmitted through the signal line, according to PAM, and convert the user data into data symbols having multiple voltage levels, the transmitter sets each of two or more sets of the user data to a first packet and a second packet, the encoder calculates a running disparity (RD) for the data symbols of the first packet and outputs an RD flag symbol based on the calculated RD value, the transmitter sequentially outputs the first packet, the RD flag symbol, and the second packet through the signal line, and the encoder determines whether to perform an operation of inverting the data symbols of the second packet according to the RD flag symbol.

According to another aspect of the inventive concept, a method of transmitting data bits includes receiving a first set of data bits to be transmitted through a signal line, performing PAM encoding on the first set of data bits to convert the data bits into data symbols having multiple voltage levels, providing look-up tables indicating a correlation between the data bits and the data symbols, the look-up tables including mappings relating to requirements of the PAM encoding, the PAM encoding requirements including a maximum transition avoidance (MTA) requirement of avoiding a maximum transition (MT) event between the data symbols and a DC balance requirement and a run-length limit requirement of the data symbols, remapping codes in a look-up table satisfying the requirements of the PAM encoding, among the look-up tables, to bit encoding patterns of the first set of data bits, and transmitting a remapped code corresponding to the first set of data bits through the signal line.

### BRIEF DESCRIPTION OF THE DRAWINGS

Embodiments will be more clearly understood from the following detailed description taken in conjunction with the accompanying drawings in which:

FIG. 1 is a block diagram illustrating an apparatus including a transmitter and a receiver according to embodiments;

FIGS. 2A and 2B are diagrams illustrating a DC wandering phenomenon on a receiver side of FIG. 1 according to embodiments;

FIG. 3 is a diagram illustrating a pulse-amplitude modulation 4 (PAM4)-symbol level for two bitstreams according to embodiments;

FIG. 4 is a diagram illustrating a PAM4 encoder according to embodiments;

FIGS. 5 to 12 are diagrams illustrating an 8B5Q coding method performed in a logic circuit of FIG. 4 according to embodiments;

FIGS. 13 and 14 are diagrams illustrating the 8B5Q encoding method according to embodiments;

FIG. 15 is a flowchart illustrating a method of operating an apparatus according to embodiments; and

FIG. 16 is a block diagram of a system for explaining an electronic device including an apparatus according to embodiments.

### DETAILED DESCRIPTION OF THE EMBODIMENTS

Multi-level signaling described in this disclosure may be used as a unit of compressing a bandwidth required to transmit data at a given bit rate. In a simple binary method, two voltage levels are generally used to represent 1 and 0, and in this case, a symbol rate may be the same as a bit rate. In comparison, in multi-level signaling, m symbols may be used to represent data, and each symbol may represent data more than 1 bit. As a result, the symbol rate is less than the bit rate and thus bandwidth may be compressed. In other words, multi-level signaling may be used to increase a data transfer rate without increasing a data transmission frequency. An example of such multi-level signaling is pulse amplitude modulation (PAM), in which multi-level signals may represent a plurality of bits of data. In PAM, the number of pulse amplitudes may be as many as powers of 2. For example, in a 4-level PAM (i.e., PAM4), there may be 22 available pulse amplitudes, and in an 8-level PAM (i.e., PAM8), there may be 23 available pulse amplitudes. However, the inventive concept is not limited thereto and may also be applied to a PAM(K) method in which there are any K (K is a natural number of 3 or greater) available pulse amplitudes.

In the PAM4 signaling described in this disclosure, maximum transition avoidance (MTA) coding may be provided so that a maximum transition (MT) event may not occur from the lowest symbol level (e.g., symbol level 0) to the highest symbol level (e.g., symbol level 3) or from the highest symbol level (e.g., symbol level 3) to the lowest symbol level (e.g., symbol level 0) between PAM4 symbols.

Data encoding schemes described in this disclosure may be used to provide multiple advantages, such as relatively low run-lengths (RL), relatively high transition density and/or DC balance, etc. In some embodiments, data encoding schemes may be used separately. Alternatively, two or more data encoding schemes may be combined or used together. Hereinafter, data encoding schemes providing DC balanced and run-length limited codes are provided.

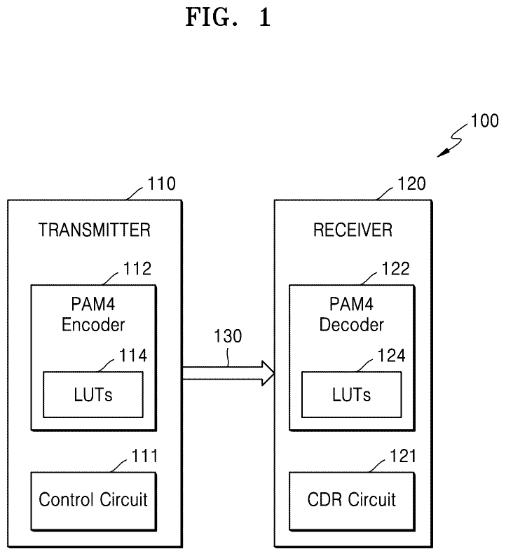

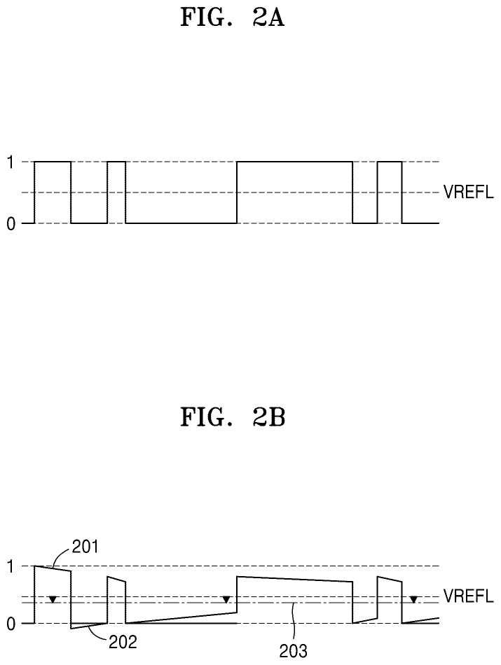

FIG. 1 is a block diagram illustrating an apparatus 100 including a transmitter and a receiver according to embodiments. FIGS. 2A and 2B are diagrams illustrating the DC wandering phenomenon on the receiver 120 side of FIG. 1 according to embodiments.

Referring to FIG. 1, the apparatus 100 may include a transmitter 110 and a receiver 120. The apparatus 100 may include a computing device, such as an integrated circuit (IC), an electronic device or system, a smartphone, a tablet PC, a computer, a server, a workstation, a portable communication terminal, a personal digital assistant (PDA), a portable multimedia player (PMP), and other suitable computers, a virtual machine, or a virtual computing device thereof. Alternatively, the apparatus 100 may be some of components included in a computing system, such as a graphics card. In the present embodiment, a number of conceptual hardware components included in the apparatus 100 are shown but the inventive concept is not limited thereto and other components are also available. The transmitter 110 may be referred to as a transmitting device, and receiver 120 may be referred to as a receiving device.

The transmitter 110 may communicate with the receiver 120 through a channel 130. The channel 130 is a plurality of signal lines that physically or electrically connect the transmitter 110 to the receiver 120. The transmitter 110, the receiver 120, and the channel 130 may support PAM4 signaling, which converts two bit streams into a single multi-level signal having four levels.

The transmitter 110 may include a control circuit 111 and a PAM4 encoder 112 that converts user data (sometimes referred to as original data) to be communicated to the receiver 120 into PAM4 symbols. The control circuit 111 may generate control signals that control an operation timing and/or a transmission operation of the transmitter 110. The control circuit 111 may provide control signals to circuits of the transmitter 110 to operate according to operation and control parameters of the transmitter 110. The control circuit 111 may input user data to the PAM4 encoder 112 using the control signals and output encoded data mapped to the user data. Although the control circuit 111 and the PAM4 encoder 112 are shown as separate components in FIG. 1, the control circuit 111 and the PAM4 encoder 112 may be implemented as an inseparable component.

The PAM4 encoder 112 may generate PAM4 symbols by encoding the user data. The PAM4 encoder 112 is generally implemented by hardware, firmware, software, or a combination thereof to form an encoding circuit. The transmitter 110 may include an output driver for driving the PAM4 symbols to the channel 130. The transmitter 110 may transmit the PAM4 symbols to the receiver 120 through the channel 130. Hereinafter, the PAM4 symbols may be used interchangeably with multi-level signals.

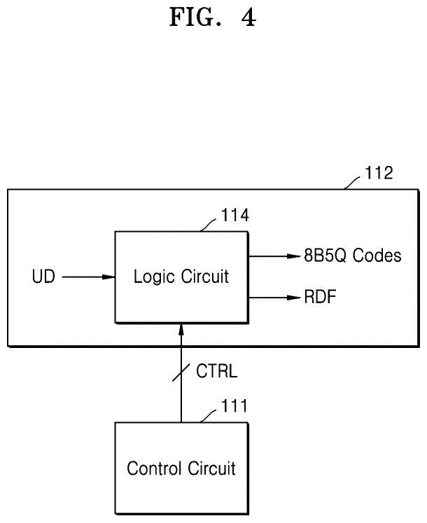

The PAM4 encoder 112 may include a logic circuit 114 implemented with registers (or storage elements) that store correlations between user data and PAM4 symbols. The logic circuit 114 may include look-up tables (LUTs) that provide DC balanced and run-length limited codes. The PAM4 encoder 112 may convert user data into PAM4 symbols using the LUTs. The PAM4 symbols may be transmitted to the channel 130 by an output driver of the transmitter 110. The logic circuit 114 is described below with reference to FIG. 4. In the following embodiments, the logic circuit 114 is described as providing DC balanced and run-length limited codes using the LUTs but is not limited thereto. For example, the logic circuit 114 corresponds to a component included in the PAM4 encoder 112, and thus, the PAM4 encoder 112 may also be described as providing DC balanced and run-length limited codes.

The receiver 120 may include a clock and data recovery (CDR) circuit 121 that receives PAM4 symbols through the channel 130 and a PAM4 decoder 122 that decodes the received PAM4 symbols. The CDR circuit 121 may generate a clock signal that is synchronized with the PAM4 symbols from the PAM4 symbols transmitted through the channel 130. The CDR circuit 121 may sample the PAM4 symbols based on the clock signal and provide the sampled PAM4 symbols to the PAM4 decoder 122.

The PAM4 decoder 122 may decode the PAM4 symbols and recover data bursts of 2 bit streams. The PAM4 decoder 122 refers to a decoder implemented in hardware, firmware, software, or a combination thereof to form a decoding circuit. The PAM4 decoder 122 may include LUTs 124 in a logic circuit implemented with registers (or storage elements) that store correlations between PAM4 symbols and user data. The PAM4 decoder 122 may restore PAM4 symbols to user data using the LUTs 124. The LUTs 124 of the PAM4 decoder 122 may be configured to be the same as the LUTs 114 of the PAM4 encoder 112.

In some embodiments, the receiver 120 may continuously receive the same PAM4 symbols through the channel 130. Here, the CDR circuit 121 may experience a DC wandering phenomenon in the voltage levels of the received PAM4 symbols and the reference voltage levels for sampling the PAM4 symbols. As an example, the transmitter 110 transmits level 0 PAM4 symbols and level 1 PAM4 symbols to the receiver 120, as shown in FIG. 2A, and the CDR circuit 121 of the receiver 120 may generate a clock signal from the transition of PAM4 symbols and perform an operation to synchronize the clock signal and received data bits. The CDR circuit 121 may compare (sometimes called sense amplification or sampling) the PAM4 symbols with a first reference voltage level VREFL in response to the clock signal and determine PAM4 symbol levels based on a comparison result.

Meanwhile, in PAM4 signaling, the channel 130 may be affected by detrimental noise sources, such as jitter, crosstalk, inter-symbol interference (ISI), and electro-magnetic interference (EMI) and cause signal distortion. As shown in FIG. 2B, distorted signals, such as the DC levels of PAM4 symbols wandering (201, 202) and the first reference voltage level VREFL fluctuating (203) may be seen. The DC wandering may be more noticeable when the same data is received repeatedly by a certain length (sometimes referred to as run-length) or greater. Accordingly, bit synchronization and sampling of the received PAM4 symbol may malfunction in the CDR circuit 121. Hereinafter, data encoding schemes for providing run-length limited codes in PAM4 signaling are described.

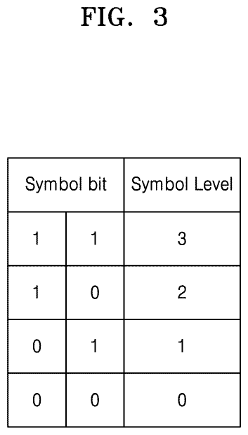

FIG. 3 is a diagram illustrating PAM4 symbol levels for two bitstreams. FIG. 3 is a non-limiting example for illustrative purposes and illustrates mapping between PAM4 symbols and symbol bits.

Referring to FIGS. 1 and 3, each of the PAM4 symbols consists of two bitstreams and may be displayed in four symbol levels. A 2-bit PAM4 symbol may be transmitted on the signal line of the channel 130 in four symbol levels indicated as level 0, 1, 2, or 3. Each of the four symbol levels may have one of four voltage levels. As an example, the PAM4 symbol at level 3 may be represented by symbol bit 11 and may be set to have the highest voltage level. The PAM4 symbol at level 2 may be represented by symbol bit 10 and may be set to have a lower voltage level than the PAM4 symbol at level 3. The PAM4 symbol at level 1 may be represented by symbol bit 01 and may be set to have a lower voltage level than the PAM4 symbol at level 2. The PAM4 symbol at level 0 may be represented by symbol bit 00 and may be set to have the lowest voltage level. Accordingly, the PAM4 symbol at level 3 may be set to have the highest power consumption, and the PAM4 symbol at level 0 may be set to have the lowest power consumption.

The PAM4 encoder 112 may be provided with MTA coding so that no maximum transition (MT) event occurs from symbol level 0 to symbol level 3 or from symbol level 3 to symbol level 0 between PAM4 symbols.

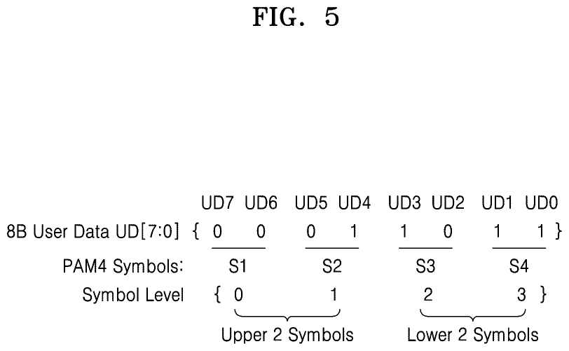

FIG. 4 is a diagram illustrating the PAM4 encoder 112 according to embodiments. The PAM4 encoder 112 of FIG. 4 may encode 8B user data UD and map the same to a 5 quaternary (5Q) symbol (sometimes referred to as 5 symbol (5S)) that satisfies DC balance and run-length limited requirements. FIGS. 5 to 12 are diagrams illustrating an 8B5Q coding method performed in the logic circuit 114 of FIG. 4.

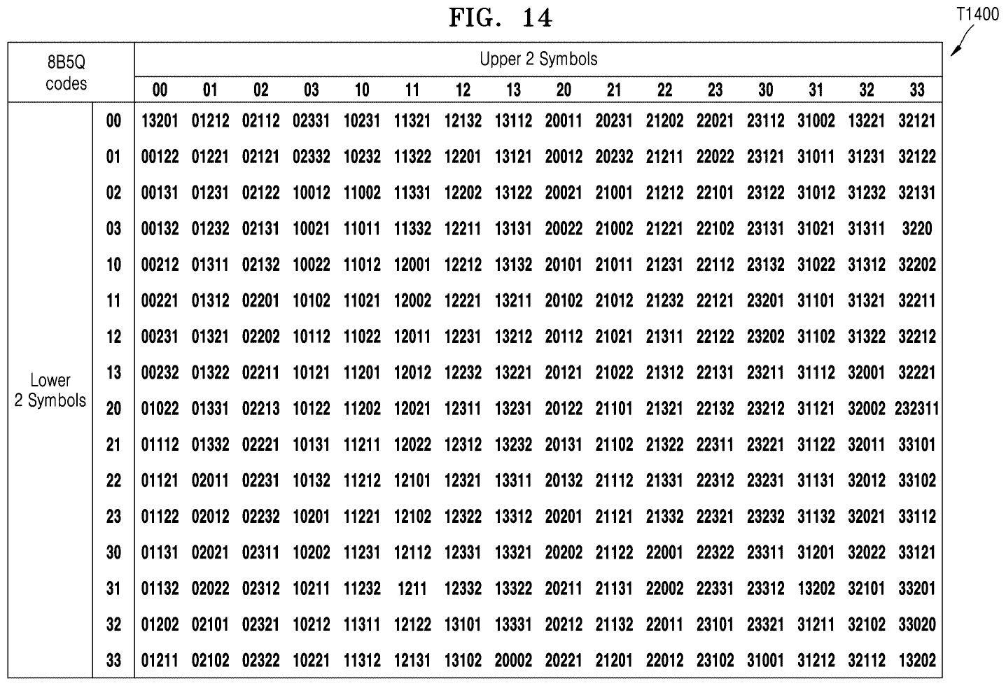

Referring to FIG. 4, the PAM4 encoder 112 may include the logic circuit 114 that provides DC balance and run-length limited 8B5Q code mapping corresponding to the 8B user data UD. The logic circuit 114 may include a look-up table T1400 (FIG. 14) including DC balanced and run-length limited 8B5Q codes. For convenience of description, code terms, entry terms, and encoded pattern terms related to the look-up table(s) provided as results of the logic operation(s) of the logic circuit 114 may be referred to interchangeably.

The logic circuit 114 may perform various logic operations based on a control signal CTRL provided from the control circuit 111. The logic circuit 114 may perform more than one logic operation on user data UD or on intermediate results of the logic operations on the user data UD. The logic circuit 114 may perform logic operations in a programmable or configurable manner in response to the control signal CTRL.

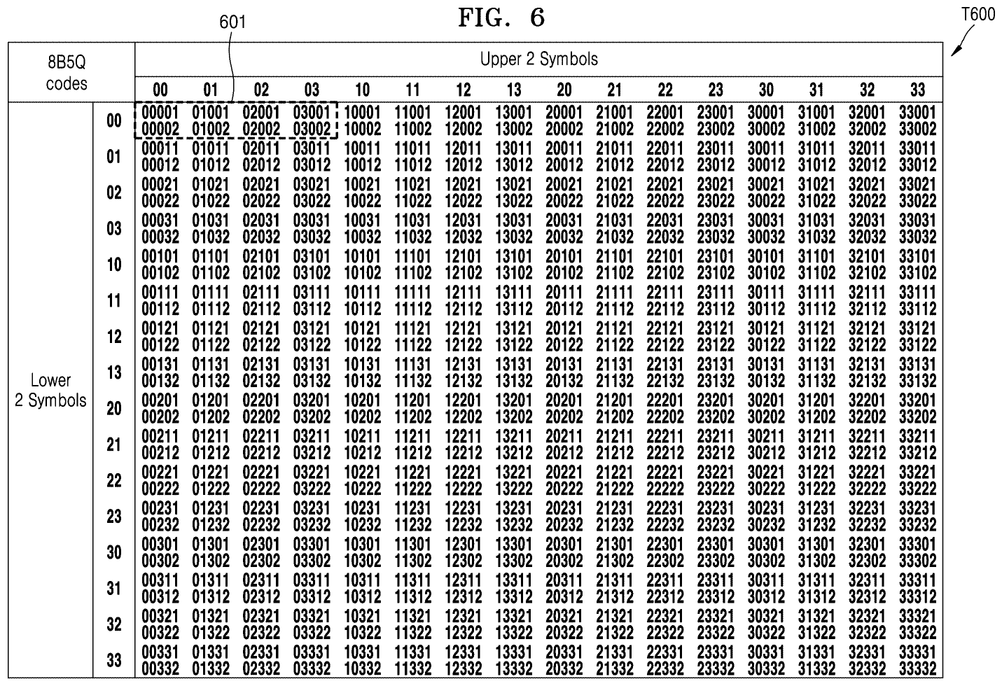

In some embodiments, the logic circuit 114 may map 8B user data UD into four PAM4 symbols. The logic circuit 114 may generate 256 patterns by performing level encoding of upper two symbols (upper 2 symbols) and lower two symbols (lower 2 symbols). The logic circuit 114 may add one edge symbol having a symbol level 1 or 2 to the end of the 256 level-encoded patterns of the upper two symbols and the lower two symbols. Accordingly, the logic circuit 114 may provide a first LUT T600 (FIG. 6) including encoded patterns including 256×2=512 entries as results of logic operations.

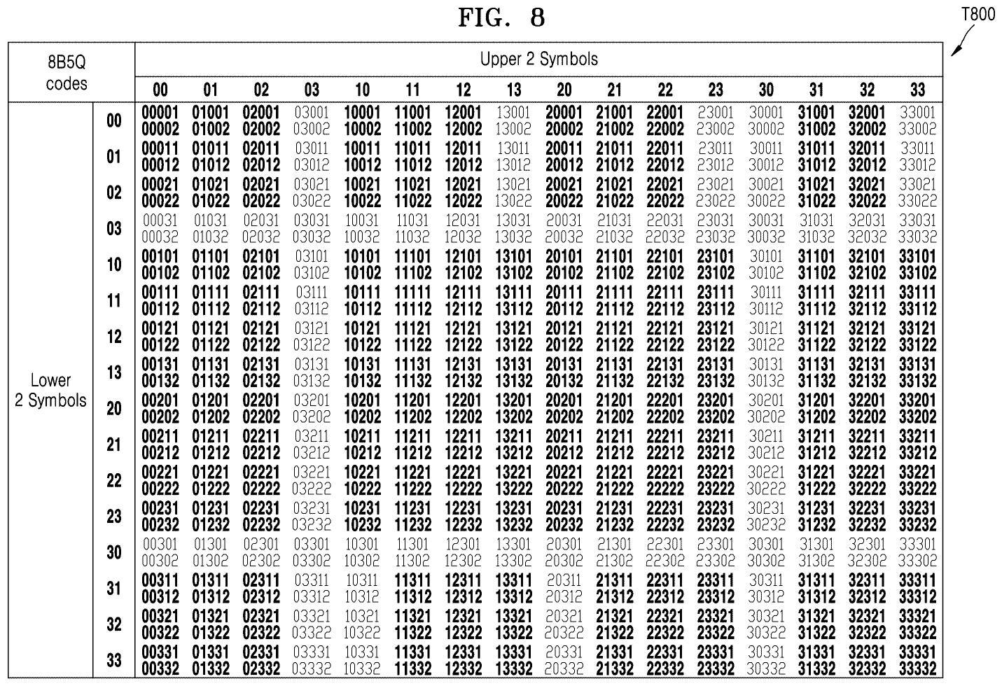

In some embodiments, the logic circuit 114 may be implemented to support MTA for the first LUT T600. The logic circuit 114 may determine and eliminate an entry with the MT event among the entries of the first LUT T600. The logic circuit 114 may determine and eliminate the MT event by performing a bit shift operation, an AND operation, and/or an inversion operation on the 512 entries of the first LUT T600. The logic circuit 114 may determine and eliminate an entry having a symbol level 03 or 30 among the upper two symbols among the 512 entries of the first LUT T600, as an MT event. The logic circuit 114 may determine and eliminate an entry having a symbol level 03 or 30 among the lower two symbols, as an MT event. The logic circuit 114 may determine and eliminate an entry in which S2 and S3 symbols, which are the boundaries of the upper two symbols S1 and S2 and the lower two symbols S3 and S4, have symbol level 03 or 30, as an MT event. The logic circuit 114 may eliminate MT events from among the 512 entries of the first LUT T600 to provide a second LUT T800 (FIG. 8) having 356 entries (512−156=356).

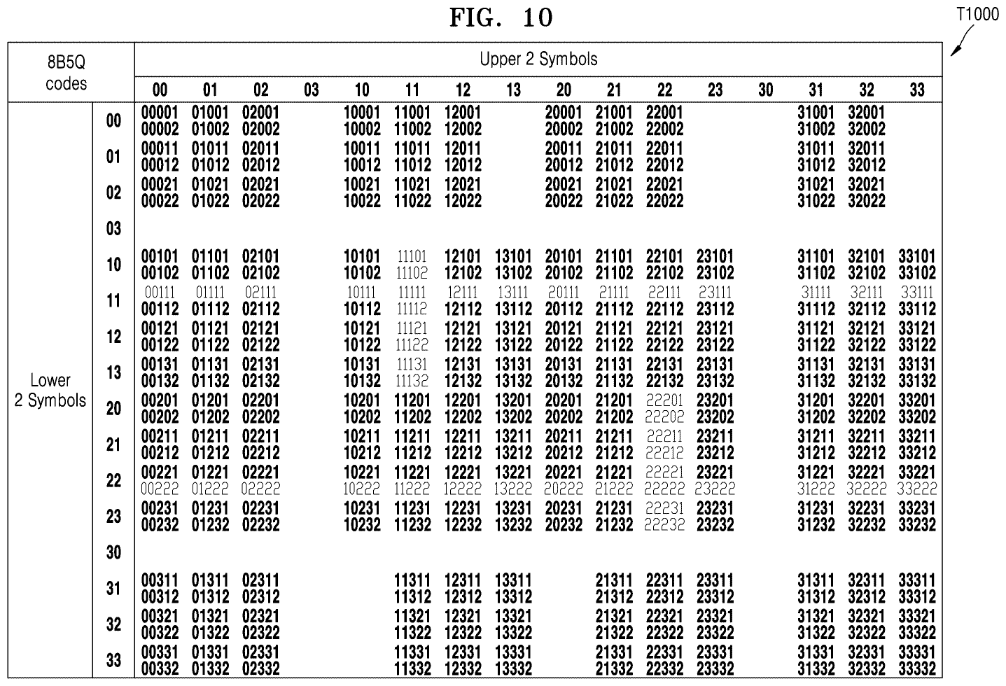

In some embodiments, logic circuit 114 may be implemented to provide run-length limited code for the second LUT T800. Because the edge symbol is set to 1 or 2 by 8B5Q code mapping, the logic circuit 114 may recognize that the run-length of symbols having the symbol level 1 or 2 does not exceed 4 and eliminate entries whose run-length may be 5 or more from the second LUT T800. The logic circuit 114 may determine an entry in which symbol levels of front three consecutive symbol sets {S1, S2, S3} and rear three consecutive symbol sets {S3, S4, S5} among five symbols for each entry, among the 356 entries of the second LUT T800, are 111 or 222, as an entry having a run-length of 5 or more and eliminate the same. The logic circuit 114 may eliminate 42 entries whose run-length may be 5 or more from among the 356 entries and provides a third LUT (T1000, FIG. 10) having 314 entries (356−42=314).

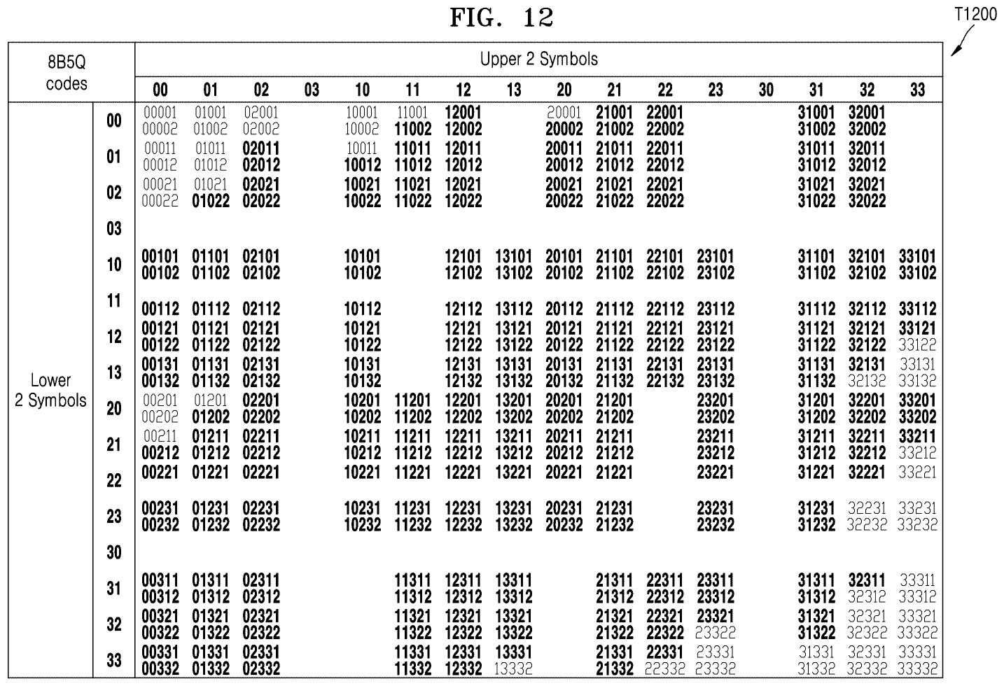

In some embodiments, the logic circuit 114 may be implemented to provide DC balanced code for the third LUT T1000. The logic circuit 114 may calculate a running disparity RD of each of the 314 entries of the third LUT T1000 and sort them in descending order from the highest absolute value of RD. The logic circuit 114 may eliminate an entry having a high absolute value of RD among the 314 entries of the third LUT T1000. The logic circuit 114 may eliminate 58 entries from among the 314 entries in order, starting from the highest absolute value of RD and provide a fourth LUT (T1200, FIG. 12) having 256 entries (314−58=256).

In some embodiments, the logic circuit 114 may be implemented to remap the 256 entries of the fourth LUT T1200 to 256 patterns according to 8-bit encoding of the user data UD[7:0]. The logic circuit 114 may remap 256 entries of the fourth LUT T1200 to 256 patterns according to 8-bit encoding of the user data UD[7:0] and provide an 8B5Q encoding table (T1400, FIG. 14) The 8B5Q encoding table T1400 may include 256 entries that are DC balanced and run-length limited.

Referring to FIGS. 3, 4, and 5, the logic circuit 114 may map 8B user data UD to four PAM4 symbols. As an example, the user data UD[7:0] may be seen as a set of data bits having a pattern {00101011}. The user data UD[7:0] may be mapped to a certain symbol set {S1, S2, S3, S4} corresponding to four PAM4 symbols for two bitstreams each. UD7:UD6 bits of the user data UD[7:0] may be mapped to the first symbol S1, UD5:UD4 bits may be mapped to the second symbol S2, UD3:UD2 bits may be mapped to the third symbol S3, and UD1:UD0 bits may be mapped to the fourth symbol S4. This is only an example to help understanding and means that they may be named as first to fourth symbols S1 to S4 according to the bit positions of the 8B user data UD.

The UD1:UD0 bit value 11 of the user data UD[7:0] may be mapped to correspond to the fourth symbol S4 with symbol level 3, the UD3:UD2 bit value 10 may be mapped to correspond to the third symbol S3 with symbol level 2, UD5:UD4 bit value 01 may be mapped to correspond to the second symbol S2 with symbol level 1, and the UD7:UD6 bit value 00 may be mapped to correspond to the first symbol S1 with symbol level 0. The first and second symbols S1 and S2 may be included in the upper two symbols, and the third and fourth symbols S3 and S4 may be included in the lower two symbols. This is only an example to help understanding and means that they may be distinguished from each other to constitute the LUT according to the combinations of the upper two symbols and the lower two symbols.

In some embodiments, the logic circuit 114 may perform level encoding of the upper two symbols and the lower two symbols using bit order scrambling and generate 256 patterns. The 256 patterns may be implemented through permutation or ordering of the symbol levels of the upper two symbols {00, 01, 02, 03, 10, 11, 12, 13, 20, 21, 22, 23, 30, 31, 32, 33} and symbol levels of the lower two symbols {00, 01, 02, 03, 10, 11, 12, 13, 20, 21, 22, 23, 30, 31, 32, 33}. The logic circuit 114 may use a multiplexer MUX to implement bit order scrambling. According to another embodiment, circuits that use a switch matrix may be employed to accommodate bit order permutation or ordering.

In some embodiments, the logic circuit 114 may allow one edge symbol having the symbol level 1 or 2 to be included at the very end of the 256 patterns provided as a result of the level encoding of the upper two symbols and the lower two symbols. Accordingly, the logic circuit 114 may provide the first LUT T600 including 256×2=512 pieces of encoded data, as shown in FIG. 6.

As an example, in the first LUT T600, a first sub-table 601 corresponding to symbol level {00, 01, 02, 03} of the upper two symbols, the symbol level {00} of the lower two symbols, and the edge symbol level {1, 2} may be seen. The first sub-table 601 may include pattern 00001 encoded by adding edge level 1 to pattern 0000 in which the 00 symbol level of the upper two symbols and the 00 symbol level of the lower two symbols are scrambled and include pattern 00001 encoded by adding edge level 2 thereto. Similarly, the first sub-table 601 may include pattern 01001 encoded by adding edge level 1 to pattern 0100 in which the 01 symbol level of the upper two symbols and the 00 symbol level of the lower two symbols are scrambled and include pattern 01002 encoded by adding edge level 2 thereto, may include pattern 02001 encoded by adding edge level 1 to pattern 0200 in which the 02 symbol level of the upper two symbols and the 00 symbol level of the lower two symbols are scrambled and include pattern 02002 encoded by adding edge level 2 thereto, and may include pattern 03001 encoded by adding edge level 1 to pattern 0300 in which the 03 symbol level of the upper two symbols and the 00 symbol level of the lower two symbols are scrambled and include pattern 03002 encoded by adding edge level 2 thereto. By this scrambling method, the first LUT T600 has 512 entries.

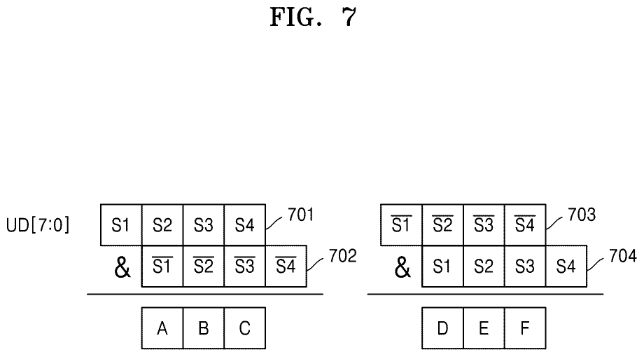

Referring to FIG. 7, the logic circuit 114 may be implemented to support MTA for the first LUT T600. Whether there is an MT event among the encoded patterns of the first LUT T600 may be determined. Among the encoded patterns of the first LUT T600, pattern 0011 or 1100 is a case in which the MT occurs. In other words, the MT event occurs when consecutive symbol levels are 03 or 30.

In some embodiments, the logic circuit 114 may map the 8B user data UD[7:0] to the first symbol set {S1, S2, S3, S4} each corresponding by two bitstreams in order to determine the MT event (701). The logic circuit 114 may perform an operation of shifting the UD[7:0] user data to the right by 2 bits and perform an operation of inverting the 2-bit shifted data. Accordingly, the inverted data may include a second symbol set {/S1, /S2, /S3, /S4} shifted by 1 symbol (702). The logic circuit 114 may perform an AND operation on the first symbol set {S1, S2, S3, S4} and the second symbol set {/S1, /S2, /S3, /S4} shifted by 1 symbol. Accordingly, symbol A may be output as a result of performing an AND operation on the S2 symbol of the first symbol set and the /S1 symbol of the second symbol set, symbol B may be output as a result of performing an AND operation on the S3 symbol of the first symbol set and the /S2 symbol of the second symbol set, and symbol C may be output as a result of performing an AND operation on the S4 symbol of the first symbol set and the /S3 symbol of the second symbol set. The logic circuit 114 may determine that the output symbol having bit value 11 in the first output symbol set {A, B, C} is an MT event.

In the present embodiment, the logic circuit 114 may perform an MT event determination operation based on an operation of shifting the user data UD[7:0] to the right by 2 bits each time. This is only an example to aid understanding, and conversely, the logic circuit 114 may perform an MT event determination operation based on an operation of shifting the user data UD[7:0] to the left by 2 bits each time.

In some embodiments, in order to more reliably determine the MT event, the logic circuit 114 may invert the first symbol set {S1, S2, S3, S4} and map the same the third symbol set {/S1, /S2, S3, /S4} (703). The logic circuit 114 may perform an operation of shifting the third symbol set {/S1, /S2, /S3, /S4} by 1 symbol and then inverting the third symbol set {/S1, /S2, /S3, /S4}. Accordingly, a fourth symbol set {S1, S2, S3, S4} shifted by 1 symbol may be configured (704). The logic circuit 114 may perform an AND operation on the third symbol set {/S1, /S2, /S3, /S4} and the fourth symbol set {S1, S2, S3, S4} shifted by 1 symbol. Accordingly, symbol D may be output as a result of performing the AND operation on the /S2 symbol of the third symbol set and the S1 symbol of the fourth symbol set, symbol E may be output as a result of performing the AND operation on the /S3 symbol of the third symbol set and the S2 symbol of the fourth symbol set, and symbol F may be output as a result of performing the AND operation on the /S4 symbol of the third symbol set and the S3 symbol of the fourth symbol set. The logic circuit 114 may determine that the output symbol having bit value 11 in the second output symbol set {D, E, F} is an MT event.

The logic circuit 114 may determine the MT event for the encoded patterns of the first LUT T600 (FIG. 6) and eliminate the MT event patterns. The logic circuit 114 may determine that an entry having symbol level 03 or 30 among the upper two symbols among the 512 entries of the first LUT T600 is an MT event and eliminate the same. The logic circuit 114 may determine that an entry having symbol level 03 or 30 among the lower two symbols is an MT event and eliminate the same. The logic circuit 114 may determine an entry in which S2 and S3 symbols, which are the boundaries between the upper two symbols S1 and S2 and the lower two symbols S3 and S4, have symbol level 03 or 30, as an MT event and eliminate the same. Accordingly, as shown in FIG. 8, the logic circuit 114 may eliminate 156 MT events from 512 entries and provide the second LUT T800 having 356 entries (512−156=356). Hereinafter, in order to simplify symbol correlation in the LUT(s), the entries eliminated by the corresponding logic operation(s) are expressed lightly, and the entries eliminated by the previous logic operation(s) are deleted because they do not exist.

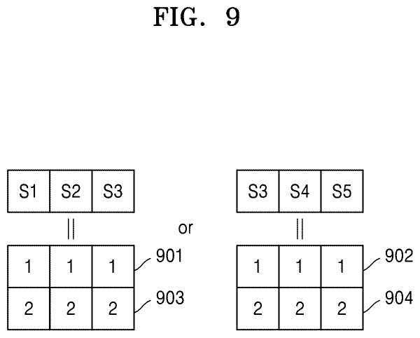

Referring to FIG. 9, the logic circuit 114 may be implemented to provide run-length limited encoded data to the second LUT T800. The logic circuit 114 may select an entry having a run-length of 4 from among 356 entries in the second LUT T800. The logic circuit 114 may recognize that the run-length of symbols having symbol level 0 or 1 does not exceed 4 because the edge symbol is set to 1 or 2 by the 8B5Q code mapping of FIG. 6. The logic circuit 114 may determine an entry having a run-length of 5 or more in the second LUT T800.

In some embodiments, the logic circuit 114 may search for an entry in which the symbol level of the front three consecutive symbol set {S1, S2, S3} is 111 (901) and the symbol level of the rear three consecutive symbol set {S3, S4, S5} is 111 (902), among the five symbols of the 8B5Q code. Such an entry may be determined to have a run-length of 5 or more. In addition, the logic circuit 114 may search for an entry in which the symbol level of the front three consecutive symbol set {S1, S2, S3} is 222 (903) and the symbol level of the rear three consecutive symbol set {S3, S4, S5} is 222 (904), among the five symbols of the 8B5Q code. Such an entry may be determined to have a run-length of 5 or more.

The logic circuit 114 may determine and eliminate the entry having the run-length of 5 among the 356 entries of the second LUT T800. Accordingly, as shown in FIG. 10, the logic circuit 114 may eliminate 42 run-length 5 entries from 356 entries and provide the third LUT T1000 having 314 (356−42=314) entries.

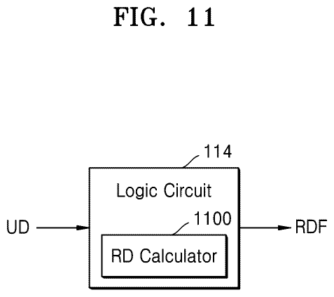

Referring to FIG. 11, the logic circuit 114 may be implemented to provide a maximum DC balanced code to the third LUT T1000 in order to reduce power consumption and/or DC wandering. The logic circuit 114 may include a running disparity RD calculator 1100 that calculates an RD of an entry in the third LUT T1000. The RD calculator 1100 may calculate the RD of each of the 314 entries of the third LUT T1000 and sort the 314 entries in descending order from the highest absolute value of RD.

In some embodiments, the RD calculator 1100 may calculate the RD of each of the 314 entries of the third LUT T1000 using Equation 1.

[Equation 1]

RD=(+3)×A+(+1)×B+(−1)×C+(−3)×D

Here, RD denotes a running disparity value for the corresponding entry, A denotes the number of symbol level 3 of the corresponding entry, B denotes the number of symbol level 2, C denotes the number of symbol level 1, and D denotes the number of symbol level 0.

The logic circuit 114 may eliminate 58 entries from among the 314 entries of the third LUT T1000, starting from the highest absolute value of RD. Accordingly, as shown in FIG. 12, the logic circuit 114 eliminates 58 entries from among the 314 entries in the order, starting from the highest absolute value of RD, and provide the fourth LTU T1200 having 256 (314−58=256).

According to some embodiments, the logic circuit 114 may remap the 256 entries of the fourth LUT T1200 to 256 patterns according to the 8-bit encoding of the user data UD[7:0]. Accordingly, the logic circuit 114 may implement the 8B5Q encoding table (e.g., T1400 in FIG. 14), and the entries in the 8B5Q encoding table T1400 may include codes having DC balance and run-length of 4.

Meanwhile, the logic circuit 114 may be implemented to provide an RD flag symbol RDF so that there is no DC wandering when continuously outputting 8B5Q codes using the 8B5Q encoding table T1400. The RD value calculated by the RD calculator 1100 may have positive (+), zero (0), or negative (−) disparity. The positive (+) disparity indicates that the number of symbol levels 3 or 2 of the corresponding 8B5Q code is greater than the number of symbol levels 1 or 0, which means that the number of bits 1 included in the corresponding 8B5Q code is greater than the number of bits 0. The negative (−) disparity indicates that the number of symbol levels 0 or 1 of the corresponding 8B5Q code is greater than the number of symbol levels 2 or 3, which means that the number of bits 0 included in the corresponding 8B5Q code is greater than the number of bits 1. The logic circuit 114 may provide an RD flag symbol RDF to ensure that there is no DC wandering, such as zero disparity (sometimes referred to as neutral disparity).

In some embodiments, the transmitter 110 may process a plurality of user data UD[7:0] to be transmitted to the receiver 120, as a set (or a sequence). As an example, the transmitter 110 may set four sets of user data UD[7:0] into one packet, and the logic circuit 114 may encode each set of user data UD[7:0] in the packet into an 8B5Q code and transmit the encoded 8B5Q codes the receiver 120.

In some embodiments, logic circuit 114 may output 8B5Q codes of a first packet, calculate RD values for the 8B5Q codes of the first packet, and output an RD flag symbol RDF based on the calculated RD values. The logic circuit 114 may output the RD flag symbol RDF having symbol level 01 or 10. The RD flag symbol RDF having symbol level 01 indicates that the 8B5Q codes of a next packet are transmitted to the receiver 120 as is, and the RD flag symbol RDF having symbol level 10 indicates that the 8B5Q codes of the next packet are inverted and transmitted to the receiver 120. This is only an example to help understanding, which means that whether invert the 8B5Q codes of the next packet may be determined by the RD flag symbol RDF having various symbol levels.

In some embodiments, the transmitter 110 may transmit to the receiver 120 in the following order: first packet—first RD flag—second packet—second RDF flag—third packet. When the first RD flag RDF has symbol level 01, the 8B5Q code of the second packet may be transmitted to the receiver 120 as is. When the second RD flag RDF has symbol level 10, the 8B5Q code of a third packet may be inverted and transmitted to the receiver 120. For example, when the 8B5Q code of the third packet has symbol level 32101, the third packet inverted to symbol level 01232 may be transmitted. That is, symbol level 3 may be inverted to symbol level 0, symbol level 2 may be inverted to symbol level 1, symbol level 1 may be inverted to symbol level 2, and symbol level 0 may be inverted to symbol level 3.

In some embodiments, it may be an overhead for the apparatus 100 that the transmitter 110 additionally transmits an RD flag RDF between packets transmitted to the receiver 120. The transmitter 110 may set the number of sets of user data UD[7:0] constituting the packet to vary within the overhead that the apparatus 100 may tolerate. As an example, the transmitter 110 may determine that two or more sets of user data UD[7:0], for example, 3 sets, 4 sets, or 5 sets, are included in one packet.

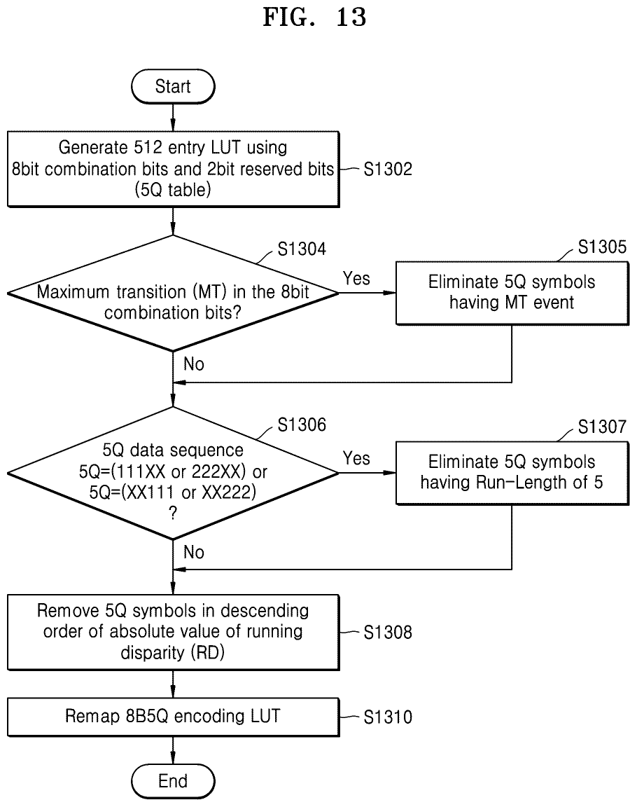

FIGS. 13 and 14 are diagrams illustrating an 8B5Q encoding method according to embodiments. FIG. 13 is a flowchart illustrating the 8B5Q encoding method described above with reference to FIGS. 1, 2A, 2B and 3 to 12, and FIG. 14 shows an 8B5Q encoding table implemented as a result of the 8B5Q encoding method of FIG. 13.

Referring to FIG. 13, in operation S1302, the logic circuit 114 of the PAM4 encoder 112 may generate the first LUT (T600 in FIG. 6) including 512 entries using 8-bit (8B) combination bits and 2-bit (2B) reserved bits configured to be mapped into four PAM4 symbols. The 8B combination bits are bits generating 256 patterns by performing level encoding on upper two symbols and lower two symbols by the 8B user data UD, and the 2B reserved bits are bits generating one edge symbol having symbol level 1 or 2 added to the end of the 256 patterns.

In operation S1304, the logic circuit 114 may determine the entry having an MT event among the entries of the first LUT T600. The logic circuit 114 may determine an entry having a symbol level 03 or 30, among the upper two symbols of the 8B combination bits as an MT event, determine an entry having a symbol level 03 or 30 among the lower two symbols as an MT event, and determine an entry having a symbol level 03 or 30, and an entry in which the boundary symbols of the upper two symbols and the lower two symbols have symbol level 03 or 30 may be determined as an MT event.

In operation S1305, the logic circuit 114 may provide the second LUT T800 (FIG. 8) by eliminating the MT event from 512 entries in the first LUT T600. The second LUT T800 may include 356 entries (512−156=356) by eliminating 156 entries having the MT event from among the 512 entries in the first LUT T600.

In operation S1306, the logic circuit 114 may determine a run-length limited entry among the 356 entries of the second LUT T800. Regarding the 356 entries of the second LUT T800, the logic circuit 114 may determine an entry in which front three consecutive symbol sets {S1, S2, S3} and the rear three consecutive symbol sets {S3, S4, S5} is 111 or 222, among the five symbols of each of the entries, as an entry having a run-length of 5 or more.

In operation S1307, the logic circuit 114 may provide the third LUT T1000 (FIG. 10) by eliminating the entry having the run-length of 5 or more from among the 356 entries in the second LUT T800. The third LUT T1000 may include 314 (356−42=314) entries by eliminating 42 entries having the run-length of 5 or more among the 356 entries of the second LUT T800.

In operation S1308, the logic circuit 114 may calculate the running disparity RD of each of the 314 entries in the third LUT T1000, eliminate the entry having a high absolute value of RD from among the 314 entries, and provide the fourth look-up table (T1200, FIG. 12) The fourth LUT T1200 may include 256 entries (314−58=256) by eliminating 58 entries, starting from the highest absolute value of RD, from among the 314 entries of the third LUT T1000.

In operation S1310, the logic circuit 114 may remap 256 entries of the fourth LUT T1200 to 256 patterns according to 8-bit encoding of user data UD[7:0]. Accordingly, as shown in FIG. 14, the logic circuit 114 may provide the 8B5Q encoding table T1400 in which the 8B user data UD[7:0] shows a correlation between level encoding of the upper two symbols and the lower two symbols and the 5Q symbols. The 8B5Q encoding table T1400 may include 256 entries having a DC balance and a run-length of 4.

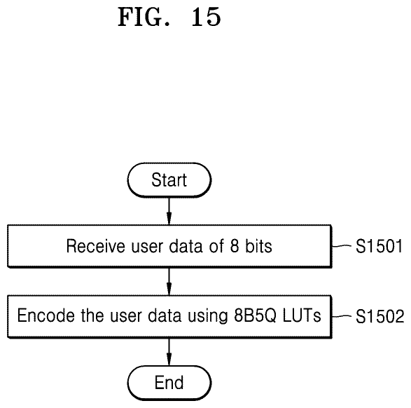

FIG. 15 is a flowchart illustrating an operating method of the apparatus 100 according to embodiments. In FIG. 15, some of operations of the transmitter 110 transmitting the 8B5Q code mapped to the 8B user data UD[7:0] to the receiver 120 through a signal line of the channel 130 using the 8B5Q encoding table T1400 providing DC balanced and run-length limited codes described above with reference to FIGS. 1, 2A, 2B and 3 to 14.

Referring to FIG. 15, in operation S1501, the transmitter 110 may receive 8B user data UD[7:0] to be transmitted on the signal line of the channel 130. In operation S1502, the transmitter 110 may encode the 8B user data UD[7:0] into an 8B5Q code using the 8B5Q encoding table T1400 provided by the logic circuit 114 of the PAM4 encoder 112.

In some embodiments, the transmitter 110 may map the 8B user data UD[7:0] to four PAM4 symbols according to PAM4 modulation by logic operations of the logic circuit 114, generate 256 patterns by performing level encoding of upper two symbols and lower two symbols among the 4 PAM4 symbols, add one edge symbol having symbol level 1 or 2 to the end of the 256 patterns, and provide the first LUT T600 including 512 entries including five PAM4 symbols.

In some embodiments, the transmitter 110 may, by logic operations of the logic circuit 114, determine and eliminate, as a maximum transition MT, an entry having symbol level 03 or 30, among the upper two symbols in the 512 entries of the first LUT T600, determine and eliminate, as an MT event, an entry having symbol level 03 or 30 among the lower two symbols, determine and eliminate, as an MT event, an entry in which boundary symbols of the upper two symbols and the lower two symbols have symbol level 03 or 30, and provide the second LUT T800 including 356 entries including five PAM4 symbols.

In some embodiments, the transmitter 110 may, by logic operations of the logic circuit 114, determine and eliminate, as an entry having a run-length of 5 or more, an entry in which front three consecutive symbol set and rear three consecutive symbol set of five PAM4 symbols of each of the 356 entries of the second LUT T800 are 111 or 222, and provide the third LUT T1000 including 314 entries including five PAM4 symbols.

In some embodiments, the transmitter 110 may, by the logic operations of the logic circuit 114, calculate RD of each of the entries of the third LUT T1000, eliminate entries, starting from the highest absolute value of RD, among the entries of the third LUT T1000, and provide the fourth LUT T1200 including 256 entries including five PAM4 symbols.

In some embodiments, the transmitter 110 may, by the logic operations of the logic circuit 114, remap the 256 entries of the fourth LUT T1200 to 256 patterns according to 8 bit encoding of the user data UD[7:0] to provide 8B5Q encoding table T1400. The 8B5Q encoding table T1400 may include 8B5Q codes that are DC balanced and have a run-length of 4.

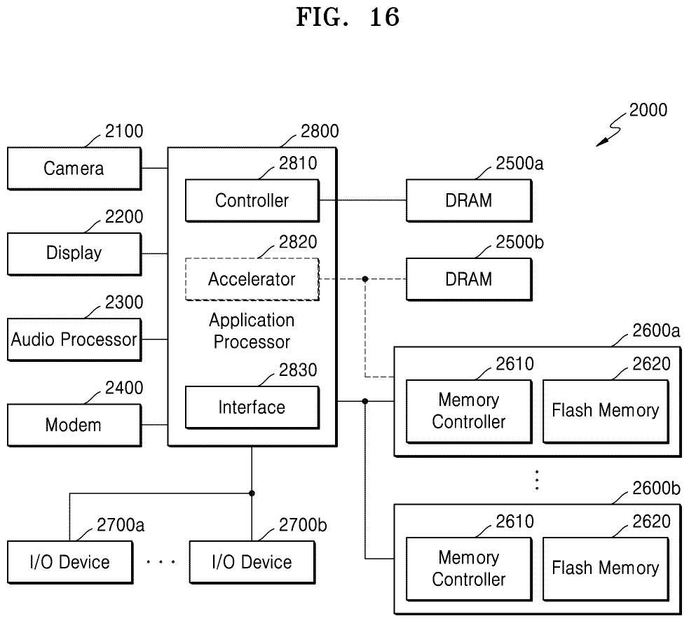

FIG. 16 is a block diagram of a system 2000 illustrating an electronic device including the apparatus 100 according to embodiments.

Referring to FIG. 16, the system 2000 includes a camera 2100, a display 2200, an audio processor 2300, a modem 2400, DRAMs 2500a and 2500b, storages 2600a and 2600b, input/output (I/O) devices 2700a and 2700b, and an application processor (AP) 2800. The system 2000 may be implemented as a laptop computer, a mobile phone, a smartphone, a tablet personal computer (PC), wearable device, healthcare device, or Internet of things (IOT) device. In addition, the system 2000 may be implemented as a server or personal computer.

The camera 2100 may capture still images or videos under user control and store or transmit the captured image/video data to the display 2200. The audio processor 2300 may process audio data included in the storages 2600a and 2600b or network content. The modem 2400 may modulate and transmit signals for wired/wireless data transmission and reception, and a receiving side may demodulate the modulated signal to recover the original signal. The I/O devices 2700a and 2700b may include devices providing a digital input and/or output function, such as a universal serial bus (USB) or a storage, a digital camera, a secure digital (SD) card, a digital versatile disc (DVD), a network adapter, a touch screen, and the like.

The AP 2800 may control an overall operation of the system 2000. The AP 2800 may include a control block 2810, an accelerator block or accelerator chip 2820, and an interface block 2830. The AP 2800 may control the display 2200 so that part of the content stored in the storages 2600a and 2600b is displayed on the display 2200. When a user input is received through the I/O devices 2700a and 2700b, the AP 2800 may perform a control operation corresponding to the user input. The AP 2800 may include an accelerator block, which is a dedicated circuit for artificial intelligence (AI) data operation or may include an accelerator 2820 separate from the AP 2800. The DRAM 2500b may be additionally mounted on the accelerator block or accelerator chip 2820. The accelerator is a function block that specializes in performing a specific function of the AP 2800. The accelerator may include a graphics processing unit (GPU), which is a function block that specializes in graphics data processing, a neural processing unit (NPU), which is a block that specializes in AI calculation and inference, and a data processing unit (DPU), which is a block that specializes in data transmission. As an embodiment, an image taken by the user through the camera 2100 is signal-processed and stored in the DRAM 2500b, and the accelerator block or accelerator chip 2820 may perform an AI data operation to recognize data using data stored in the DRAM 2500b and a function used in an inference.

The system 2000 may include a plurality of DRAMs 2500a and 2500b. The AP 2800 may control the DRAMs 2500a and 2500b through command and mode register (MRS) settings that meet the Joint Electron Device Engineering Council (JEDEC) standard or may set a DRAM interface protocol to perform communication to use company-specific functions, such as low voltage/high speed/reliability and a cyclic redundancy check (CRC)/error correction code (ECC) function. For example, the AP 2800 may communicate with the DRAM 2500a through an interface that complies with JEDEC standards, such as LPDDR4 and LPDDR5, and the accelerator block or accelerator chip 2820 may set a new DRAM interface protocol to perform communication to control the DRAM 2500b for an accelerator having a bandwidth higher than that of the DRAM 2500a.

In FIG. 16, only DRAMs 2500a and 2500b are shown, but without being limited thereto, any memory, such as phase-change random access memory (PRAM), static random access memory (SRAM), magnetoresistive random access memory (MRAM), resistive random access memory (RRAM), ferroelectric random access memory (FRAM), or hybrid RAM, that may satisfy a bandwidth, a response speed, and voltage conditions of the AP 2800 or the accelerator chip 2820 may be used. The DRAMs 2500a and 2500b have relatively smaller latency and bandwidth than the I/O devices 2700a and 2700b or the storages 2600a and 2600b. The DRAMs 2500a and 2500b may be initialized when the system 2000 is powered on, and an operating system and application data may be loaded to the DRAMs 2500a and 2500b so that the DRAMs 2500a and 2500b may be used as temporary storage locations for the operating system and application data or as an execution space for various software codes.

In the DRAMs 2500a and 2500b, four arithmetic operations of addition/subtraction/multiplication/division, vector operations, address operations, or fast Fourier transform (FTT) operations may be performed. In addition, a function used for inference may be performed within the DRAMs 2500a and 2500b. Here, inference may be performed in a deep learning algorithm using an artificial neural network. The deep learning algorithm may include a training operation to train a model through various data and an inference operation to recognize data with the trained model.

The system 2000 may include the storages 2600a and 2600b with larger capacities than capacities of the DRAMs 2500a and 2500b. The accelerator block or accelerator chip 2820 may perform a training operation and AI data operation using the storages 2600a and 2600b. In an embodiment, the storages 2600a and 2600b may each include a memory controller 2610 and a flash memory 2620 and may more efficiently perform the training operation and the inference AI data operation performed by the AP 200 and/or the accelerator chip 2820 using an arithmetic operation device provided in the memory controller 2610. The storages 2600a and 2600b may store images captured through the camera 2100 or store data transmitted over a data network. For example, the storages 2600a and 2600b may store augmented reality/virtual reality, high definition (HD), or ultra-high definition (UHD) content.

The components of the system 2000 may include semiconductor devices and/or memory devices using the 8B5Q encoding method providing DC balanced and run-length limited codes described above with reference to FIGS. 1, 2A, 2B and 3 to 15. The semiconductor devices and/or memory devices may include a transmitter that transmits data bits. The transmitter may perform pulse amplitude modulation (PAM) encoding on data bits to be transmitted on a signal line and convert the data bits into data symbols having multiple voltage levels, and provide LUTs representing the correlation between the data bits and the data symbols. The LUTs include codes that satisfy the MTA requirements between data symbols and the DC balance requirements and run-length limit requirements of the data symbols, and the codes of a final LUT may be remapped to bit encoding patterns of the data bits. The transmitter may set a set of two or more user data to a first packet and a second packet, calculate an RD for data symbols of the first packet, output an RD flag symbol based on the calculated RD value, and determine whether to perform an operation of inverting the data symbols of the second packet according to the RD flag symbol. Through an apparatus implementing the encoding scheme(s) of the inventive concept, data recovery in a CDR circuit may be facilitated and the data eye size may be expanded. The improved function of the apparatus may be usefully applied to high-speed communication devices and systems.

While the inventive concept has been particularly shown and described with reference to embodiments thereof, it will be understood that various changes in form and details may be made therein without departing from the spirit and scope of the present invention as set forth in the following claims.

What is claimed is:

1. An apparatus comprising:
a transmitter connected to a signal line, the transmitter including an encoder configured to:
encode data bits to be transmitted through the signal line, according to pulse amplitude modulation (PAM), and
convert the data bits into data symbols having multiple voltage levels,
wherein the encoder includes:
a logic circuit configured to provide look-up tables indicating a correlation between the data bits and the data symbols, the look-up tables including mappings related to operation requirements of the encoder, the operation requirements of the encoder including a direct current (DC) balance requirement and a run-length limit requirement of the data symbols, and
a control circuit configured to selectively control logic operations of the logic circuit that generates the look-up tables.

2. The apparatus of claim 1, wherein:
the logic circuit is configured to map 8-bit user data included in the data bits to four data symbols, generate 256 patterns by performing level encoding of upper two symbols and lower two symbols among the four data symbols, and provide a first look-up table including five data symbols by adding one edge symbol having symbol level 1 or 2 to the end of the 256 patterns, and
the multiple voltage levels includes an uppermost level having symbol level 3, a lowermost level having symbol level 0, the symbol level 1 having a voltage level higher than a voltage level of the symbol level 0, and the symbol level 2 having a voltage level higher than the voltage level of the symbol level 1 and lower than a voltage level of the symbol level 3.

3. The apparatus of claim 2, wherein the first look-up table includes 512 entries including the five data symbols.

4. The apparatus of claim 2, wherein:
the operation requirements of the encoder further includes a maximum transition avoidance (MTA) requirement of avoiding a maximum transition (MT) event between the data symbols, and
the logic circuit is configured to determine and eliminate the MT event by performing a bit shift operation, an AND operation, and an inverting operation on an entry of the first look-up table.

5. The apparatus of claim 2, wherein the logic circuit is configured to provide a second look-up table by determining and eliminating, as maximum transition (MT) among the data symbols, an entry having symbol level 03 or 30 among the upper two symbols among entries of the first look-up table, by determining and eliminating, as an OKMT event, an entry having symbol level 03 or 30 among the lower two symbols, and by determining and eliminating, as an MT event, an entry in which boundary symbols of the upper two symbols and the lower two symbols have symbol level 03 or 30.

6. The apparatus of claim 5, wherein the second look-up table includes 356 entries including the five data symbols.

7. The apparatus of claim 5, wherein:
the run-length limit requirement is determined by a run-length of 4, and
the logic circuit is configured to provide a third look-up table by determining and eliminating an entry having a run-length of 5 or more among the entries of the second look-up table.

8. The apparatus of claim 7, wherein the logic circuit is configured to determine and eliminate, as the entry having a run-length of 5 or more, an entry in which symbol levels of front three consecutive symbol sets and rear three consecutive symbol sets of the five data symbols of each of the entries of the second look-up table are 111 or 222.

9. The apparatus of claim 7, wherein the third look-up table includes 314 entries including the five data symbols.

10. The apparatus of claim 7, wherein:
the logic circuit is configured to calculate a running disparity (RD) of each of entries of the third look-up table to support the DC balance requirement and eliminates an entry having a high absolute value of RD from the entries in the third look-up table to provide a fourth look-up table, and
the fourth look-up table includes 256 entries including the five data symbols.

11. The apparatus of claim 10, wherein the logic circuit is configured to provide an 8B5Q encoding table by remapping the 256 entries of the fourth look-up table to 256 patterns according to 8-bit encoding of the 8-bit user data.

12. An apparatus comprising:
a transmitter connected to a signal line, the transmitter including an encoder configured to:
encode user data to be transmitted through the signal line, according to pulse amplitude modulation (PAM), and
convert the user data into data symbols having multiple voltage levels, wherein:
the transmitter is configured to set each of two or more sets of the user data to a first packet and a second packet,
the encoder is configured to calculate a running disparity (RD) for the data symbols of the first packet and output an RD flag symbol based on the calculated RD value,
the transmitter is configured to sequentially output the first packet, the RD flag symbol, and the second packet through the signal line, and
the encoder is configured to determine whether to perform an operation of inverting the data symbols of the second packet according to the RD flag symbol.

13. The apparatus of claim 12, wherein the encoder is configured to:
set, among the multiple voltage levels, an uppermost level to have symbol level 3 and a lowermost level to have symbol level 0, symbol level 1 to have a voltage level higher than a voltage level of the symbol level 0, and symbol level 2 to have a voltage level higher than the voltage level of the symbol level 1 and lower than a voltage level of the symbol level 3, and
invert the data symbols by performing inverting the symbol level 3 to the symbol level 0, the symbol level 2 to the symbol level 1, the symbol level 1 to the symbol level 2, and the symbol level 0 to the symbol level 3.

14. The apparatus of claim 12, wherein:
the transmitter is configured to change a number of sets of the user data included in the first packet and the second packet, and
the encoder is configured to calculate the RD for the data symbols included in the changed number of sets of the user data of the first packet.

15. A method of transmitting data bits, the method comprising:
receiving a first set of data bits to be transmitted through a signal line;
performing pulse amplitude modulation (PAM) encoding on the first set of data bits to convert the data bits into data symbols having multiple voltage levels;
providing look-up tables indicating a correlation between the data bits and the data symbols, the look-up tables including mappings relating to requirements of the PAM encoding, the PAM encoding requirements including a maximum transition avoidance (MTA) requirement of avoiding a maximum transition (MT) event between the data symbols and a direct current (DC) balance requirement and a run-length limit requirement of the data symbols;
remapping codes in a look-up table satisfying the requirements of the PAM encoding, among the look-up tables, to bit encoding patterns of the first set of data bits; and
transmitting a remapped code corresponding to the first set of data bits through the signal line.

16. The method of claim 15, further comprising:
calculating a running disparity (RD) for the data symbols of a first packet;
outputting an RD flag symbol based on the calculated RD value; and
sequentially transmitting the first packet, the RD flag symbol, and a second packet through the signal line.

17. The method of claim 16, wherein the sequentially transmitting of the first packet, the RD flag symbol, and the second packet through the signal line comprises:
inverting and transmitting the data symbols of the second packet according to the RD flag symbol of a first type; and
transmitting the data symbols of the second packet as is according to the RD flag symbol of a second type.

18. The method of claim 15, wherein the providing of the look-up tables indicating the correlation between the data bits and the data symbols comprises:
mapping 8-bit user data included in the first set of data bits to four data symbols;
generating 256 patterns by performing level encoding of upper two symbols and lower two symbols among the four data symbols; and
providing a first look-up table including five data symbols by adding one edge symbol having symbol level 1 or 2 to the end of the 256 patterns,
wherein, among the multiple voltage levels, an uppermost level has symbol level 3, a lowermost level has symbol level 0, the symbol level 1 has a voltage level higher than a voltage level of the symbol level 0, and the symbol level 2 has a voltage level higher than the voltage level of the symbol level 1 and lower than a voltage level of the symbol level 3.

19. The method of claim 18, wherein the providing of the look-up tables indicating the correlation between the data bits and the data symbols comprises:
determining and eliminating, as maximum transition (MT) among the data symbols, an entry having symbol level 03 or 30 among the upper two symbols among entries of the first look-up table;
determining and eliminating, as an MT event, an entry having symbol level 03 or 30 among the lower two symbols; and
determining and eliminating, as an MT event, an entry in which boundary symbols of the upper two symbols and the lower two symbols have symbol level 03 or 30 to provide a second look-up table.

20. The method of claim 19, wherein the providing of the look-up tables indicating the correlation between the data bits and the data symbols comprises:
determining and eliminating, as the entry having a run-length of 5 or more, an entry in which symbol levels of front three consecutive symbol sets and rear three consecutive symbol sets of the five data symbols of each of the entries of the second look-up table are 111 or 222 to provide a third look-up table;
calculating a running disparity (RD) of each of entries of the third look-up table; and
eliminating an entry having a high absolute value of RD from the entries in the third look-up table to provide a fourth look-up table,
wherein an entry of the fourth look-up table is remapped to the bit encoding patterns of the first set of data bits.
